(19) United States
(12) Patent Application Publication
(10) Pub. No.: US 2020/0158809 A1
(43) Pub. Date: May 21, 2020

(54) PROCESS FOR THE CALIBRATION OF AN OBJECT UNDER TEST

(71) Applicant: esz AG calibration & metrology, Eichenau (DE)

(72) Inventor: Philip M. Fleischmann, Eichenau (DE)

(21) Appl. No.: 16/687,541

(22) Filed: Nov. 18, 2019

(30) Foreign Application Priority Data
Nov. 19, 2018 (DE) 102018009074.5

(51) Int. Cl. G01R 35/00; G01R 19/25

(52) U.S. Cl. CPC G01R 35/005; G01R 13/02; G01R 19/25

(57) ABSTRACT

A calibration process and a computer program product as well as a system comprising a test equipment and a calibration system for calibrating an object under test.

### CROSS-REFERENCE TO RELATED APPLICATIONS

This patent application incorporates by reference German Patent Application No. 10 2018 009 074.5, filed Nov. 19, 2018, titled “PROCESS FOR THE CALIBRATION OF AN OBJECT UNDER TEST.”

### FIELD OF THE INVENTION

In general, the present invention refers to the field of metrology, and in particular to a process for the calibration of an object under test.

### BACKGROUND OF THE INVENTION/STATE OF THE ART

Conventional calibration processes exhibit certain disadvantages such as error-proneness with respect to calibration, the instruments used in said calibration, or insufficient or unreliable traceability.

### OBJECT

The object of the present invention is to provide a calibration process with improvements over known approaches.

### SUMMARY OF THE INVENTION

The above problem is solved by subject matter according to the independent claims. Preferred embodiments are described in the dependent claims.

A process according to the invention for the calibration of an object under test may comprise the following steps:
providing a plurality of calibration masters by the use of a calibration system, wherein a calibration master indicates the following items:
   an assigned object under test,
   a calibration process designated for the assigned object under test and including at least one calibration value,
   a quantity to be measured for the assigned object under test,
selecting a calibration master to which the object under test is assigned,
defining requirements for the calibration of the object under test, said requirements comprising:
   a process for calculating the proximity of measured values of said quantity to be measured with respect to the corresponding calibration value and/or a measurement uncertainty;
   a specification assigned to said calibration value, the specification being determined with respect to the object under test;
defining a test equipment appropriate for the indicated quantity to be measured;
said process further comprising the following steps:
producing quantities to be measured for each calibration value by use of the defined test equipment, and
transferring each of said quantities to be measured from said test equipment to said object under test, wherein said object under test produces measured values in response to each of said transferred quantities to be measured,
acquiring each of said produced measured values by means of said calibration system,
ascertaining the proximity of each acquired measured value with respect to the determined specification by means of said calibration system using said proximity calculation process in order to verify if each of said measured values is included in said determined specification, wherein for each measured value, the proximity calculation is performed after acquiring the same,
performing conformity tests on each acquired measured value,
ascertaining, by means of said calibration system and based on the conformity tests performed, if or if not the conformity evaluation of the calibration of the object under test has been successful,
performing, by means of said calibration system, a plausibility check to verify if or if not the calibration of said object under test may be definitely approved.

A process according to the invention for the calibration of an object under test may comprise the following steps:
providing a plurality of calibration masters by means of a calibration system, a calibration master indicating the following items:
   an assigned object under test,
   a calibration process designated for the assigned object under test and including at least one calibration value,
   a quantity to be measured for the assigned object under test,
selecting a calibration master to which the object under test is assigned,
defining requirements for the calibration of the test equipment, said requirements comprising:
   a process for calculating the proximity of measured values of the quantity to be measured with respect to each calibration value and/or a measurement uncertainty;
   a specification assigned to the calibration value, the specification being determined with respect to the object under test;
defining a test equipment appropriate for the indicated quantity to be measured; said process further comprising the following steps:
producing quantities to be measured for each calibration value by use of the object under test, and
transferring each of said quantities to be measured from said object under test to said defined test equipment, wherein said test equipment produces measured values in response to each of said transferred quantities to be measured,
acquiring each of said produced measured values by means of said calibration system,
ascertaining the proximity of each acquired measured value with respect to the determined specification by means of said calibration system using said proximity calculation process in order to verify if each of said measured values is covered by said determined specification, wherein for each measured value, the proximity calculation is performed after acquiring the same,
performing conformity tests on each acquired measured value,
determining by means of said calibration system and based on the conformity tests performed, if or if not the conformity evaluation of the test specimen calibration has been successful
performing, by means of said calibration system, a plausibility check to verify if or if not the calibration of said object under test may be definitely released.

A process according to the invention may further comprise the steps according to the process for the calibration of an object under test, in which quantities to be measured are transferred from the test equipment to the object under test, wherein said object under test produces measured values in response to each transferred quantity to be measured, and/or may comprise steps according to the process for the calibration of an object under test, in which quantities to be measured are transferred from said object under test to the defined test equipment, wherein said test equipment produces measured values in response to each of said transferred quantities to be measured.

In particular, calibration may refer to a measurement process for a reliably reproducible assessment and documentation of a relationship (e.g. an offset) between the values of an object under test (e.g. a display) or a test equipment or an artifact with respect to another (measuring) instrument, standard or artifact, respectively. This process may verify the compliance with tolerance requirements, and alignments (adjustments) may the performed based on the respective results.

Usually, a calibration will be performed following repairs, maintenance work, changes of location, changes of ambient conditions, usage of measurement, test and work tools, as well as after the expiration of a fixed calibration interval (time period). An initial calibration is a first calibration of an object under test or a test equipment or an artifact, respectively, which has been unknown or has not been calibrated before.

Therefore, calibration may refer to an operation which establishes, in a first step, under or according to predetermined and/or known conditions/parameters which may also be referred to as influence quantities, a relationship between the quantity values provided by standards including respective measurement uncertainties and the readings including respective measurement uncertainties, and which uses, in a second step, information in order to establish a relationship whereby a measurement result can be obtained from a reading. The standards used may be traceable to national standards.

In order to constantly obtain reliable measurements, it is necessary to calibrate used and/or usable test equipment or standards in regular intervals. This will ensure also the traceability of test equipment or standards, inter alia. Said intervals are referred to as calibration intervals. The duration of said time period may be based e.g. on the manufacturer's instructions, the demanded measurement uncertainties and on specific quality-related determinations. For example, one demand may be that a predetermined time period from the latest calibration must not be exceeded.

A calibration value or so-called target value is a value which may be produced and/or provided or set, respectively, by a measurement standard, a test equipment or a predetermined process, and may correspondingly be measured using an object under test and/or a (measuring) instrument. However, a calibration value is also a value which is produced and/or provided or set, respectively, by an object under test or a (measuring) instrument and may correspondingly be measured by a test equipment. When objects under test which themselves deliver quantities are calibrated, the calibration value may be set, e.g. on the object under test, and a measured value may be measured, e.g. by the test equipment. The provided and/or produced or set quantities to be measured are subject to measurement uncertainties.

A measured value or actual value ist the value of a quantity to be measured that is indicated or produced/provided by the object under test. Most times, the measured value will differ from the calibration value due to measurement errors. Depending on the selected calibration process, the measured value may also be the value of a quantity to be measured indicated or produced/provided by the test equipment. It is also possible to acquire multiple measured values, for example if an object under test fluctuates significantly regarding its indication/display/output.

Stated otherwise, the allocation of calibration value or measured value may depend on the calibration process, especially on whether the quantities to be measured will be produced and transferred from the test equipment to the object under test or the other way around.

A measurement uncertainty is a range of values in which the (true) value of a variable will be found with a certain probability. The measurement uncertainty may be a value of a range in which the calibration value of a quantity to be measured may be found, for example. Measurement uncertainties may be calculated statistically and are related to the variance of the measured values of a series of measurements. Based on a demanded confidence level, the measurement uncertainty may, for example, be a multiple of the standard offset.

Predetermined and/or known calibration conditions/parameters may be indications of/information on a location and an environment where the calibration is performed, such as temperature, pressure, humidity, local gravitational acceleration, calibration site, measurement scatter, users and user-dependent information, calibration standard, reading errors or other parameters which will affect the calibration process. The calibration processes according to the invention always take into account each and every variable that will affect the calibration process (influence quantities).

It is, for example, advisable that the calibration environment, i.e. the location where the calibration of the object under test will be performed, such as the working place, the laboratory or a measuring room, is kept under constant conditions. For example, the room temperature may be held at a constant temperature of 23° C. or 20° C., but also at a different value, in order to exclude the influence of temperature fluctuations on the instruments used or the measurement results, respectively. Additionally or alternatively, brightness, air humidity, pressure, airborne particles (clean room), composition of gases and/or other conditions may be maintained constant, too. Current conditions/parameters will always be taken into account when an object under test is calibrated, and will contribute to the measurement uncertainty.

A calibration master may refer to a freely configurable template for the calibration of an object under test. A calibration master may also include an order reference such as a customer reference or instrument reference, for example. Calibration masters may be (newly) created and used (reused) at any time. It is also possible to create new versions of an existing calibration master. The calibration may be performed in parallel.

A test equipment is a measuring instrument, reference material and/or an artifact or a device which may be used as a standard with respect to the calibration of an object under test, a (measuring) instrument, reference material or artifact, respectively. In the processes according to the invention for the calibration of an object under test, the test equipment may be exchanged any time, i.e. may be replaced by different appropriate test equipment. The test equipment will constantly be inspected, and their usability will be evaluated by regular calibrations against user specifications. The test equipment is also calibrated and, as a rule, are more accurate than the object under test which needs to be calibrated. Their calibration parameters are recorded. The term “more accurate” may mean that the test equipment has a smaller measurement uncertainty than the specification to be verified, for example. This is, however, not a mandatory requirement for a test equipment.

In the calibration process according to the invention, the objects under test may comprise test equipment, reference materials or instruments for ascertaining geometrical and/or physical quantities (to be measured), for example. A quantity to be measured is the physical quantity which is subject to measurement. The objects under test which need to be calibrated may also include an artifact.

Said objects under test comprise for example instruments for measuring (mechanical and geometrical) quantities such as time, length, surface area, volume, mass, force, density, temperature, refractive index, molar concentrations; for example electrical/electronical instruments for measuring electrical quantities such as voltage, current strength, electrical field strength, electrical power/work, resistivity, conductivity, frequencies; instruments for measuring magnetic quantities such as magnetic poles (compass), magnetic field strength, magnetic flux, magnetic activity or, for example, instruments for measuring radioactivity, radiation and optical quantities such als absorbance, reflectance or emission of spectra or wavelengths, radiation doses, incident ionizing particles (radioactive radiation, X-rays), or instruments for measuring other radiation, such as alpha, beta, gamma or neutron radiation or radiation transmission.

They include also objects under test and/or test equipment such as instruments for measuring velocity, rotational speed, acceleration, as well as combinations of said instruments for assessing geometrical and/or physical quantities to be measured. They include also, for example, test stands of production facilities in the aerospace/vehicle/mechanical engineering/manufacturing fields for measuring driving dynamics, such as for example headlamp-setting test instruments, brake test stands, aerodynamics, (aero-)acoustics, aero(elastics), sound, light and comfortableness or similar test stands.

The objects under test in the calibration process according to the invention may also include artifacts, substances, substance mixtures, materials, compositions of any kind, and also gases or liquids, for example.

It should be noted that the object under test or (measuring) instrument and the test equipment or standard may also include instruments of the same type, for example two DC-voltage measuring instruments. However, in other embodiments, said instruments may differ from one another. In this context, “same type” means that the instruments have the same configuration, i.e. two DC-voltage measuring instruments, however, the test equipment may or should be more accurate in order to obtain significant results.

Tools used in the calibration process may be cables, current supplies, adaptors, load resistors, measuring tapes, instruments for the detection of ambient or calibration conditions, comparators, display devices, transfer standards, connecting elements or the like. Tools may be used to transmit and exchange information, parameters, (measurement) categories and values between the test equipment and the object under test, for example. Tools are defined as standalone instruments, however, it is not mandatory to use them in the calibration process. That is, the number and the types of tools used will depend on the object under test that needs to be calibrated. A connection may therefore also be wireless, that is, it is possible that there is no requirement to use a tool. However, if tools are used in the calibration, they will be taken into account for the calibration.

The calibration requirements may comprise a choice of (appropriate) test equipment, and a test equipment may be exchangeable, i.e. one test equipment may be replaced by a different (appropriate) calibration test equipment at any time. Defining a test equipment appropriate for the indicated quantity to be measured may in particular mean creating a (new) test equipment which has not been included in the requirements or the choice of test equipment, or selecting or designating a test equipment that has already been included in the choice or the requirements or has been only lately created. In particular, the calibration master may provide a suggestion for an appropriate test equipment or, in case an appropriate test equipment has not been created yet or does not exist, may request to create a (new) test equipment.

All requirements and indications included in the calibration master or one or more of them, or the calibration master itself may also be specific, changeable and adjustable with respect to the calibration. In particular, a zero value is also included. For example, a zero value may have been or may be entered as a specification in the calibration requirements if no specification is needed or requested. In such a case, an object under test will therefore be calibrated without that assigned specification.

That is, requirements may be different among calibrations, for example, or may be the same, depending on specific, defined demands. In case an appropriate calibration master is not existing, a new calibration master may be created any time (for example including an order reference).

A specification is an instrument and/or a user requirement (e.g. a required tolerance limit or tolerance range or zone). For the calibration of an object under test, a specification may also comprise a zero value. In particular, a specification may be customer-specific. In this case, the object under test will be calibrated without indicating a specification, for example if only a more general statement on the functionality of the object under test is required, or if it is not intended to calibrate the object under test with respect to a specification. For the calibration including the zero value in its specification, a document is required which states the reason for this kind of calibration. If a zero value is selected as a specification, a conformity assessment statement may be omitted.

In one, some or all process(es) according to the invention for calibrating an object under test, a results report and/or a calibration accreditation may be produced, as well as a label of the object under test which may be e.g. optional. A label may be e.g. a calibration seal, which states, for example, that the object under test has been calibrated (e.g. successfully).

A calibration accreditation records the performed calibration of a test equipment or object under test. To this end, instrument data of said test equipment or said object under test may be acquired, as well as the measured data measured during calibration. For example, the contents of the calibration accreditation may state the laboratory that performed the measurements, the site where and the conditions under which the calibration was performed, the test equipment used, the process used, the offsets and measurement uncertainties ascertained, and which specifications (if predetermined) have been met or fulfilled, respectively. The calibration accreditation may automatically be output or generated in one or more languages, i.e. “at the push of a button”. A calibration accreditation serves to assure quality, inter alia.

A calibration seal proves that an instrument has been calibrated, and may bear a unique number in order to allow the allocation with an associated calibration accreditation including the measured values ascertained. Moreover, the calibration seal may comprise a calibration date and a code which allows to retrieve said calibration seal any time, e.g. online, and/or a date of the next calibration.

Furthermore, one or some or all process(es) according to the invention for the calibration of an object under test may output a results report (i.e. the calibration certificate), als well as the label of the object under test. It is also possible to execute an approval of the calibration and the results report (i.e. the calibration certificate) in order to store them definitely.

Conformity tests may refer to the verification of conformity for each measured value, for example immediately after the acceptance/receipt of a measured value and the calculation of its proximity. That is, conformity tests may be performed for each individual measured value immediately after acquiring the same. In addition to this, a decision rule may be required for said conformity tests, for example in order to be able to perform a proximity evaluation with respect to the tolerance zone. A tolerance evaluation may be controlled with or without taking into account the measurement uncertainty.

A conformity evaluation may be considered as presentation and/or assessment indicating that determined and/or predetermined demands regarding a product, a procedure, a system, a person or a site are met, for example the compliance of an object under test with a regular standard, manufacturer's instruction, use instruction, guideline, user and/or industrial requirement. They may be referred to as conformity requirements.

In particular, it will be determined for all measured values or calibration values if or if not a calibration object or an object under test to be calibrated is covered by a specification, for example by a (e.g. determined or predetermined) tolerance zone. According to the calibration process of the invention, an individual evaluation is performed for each single measurement step and/or measured value of a quantity to be measured upon acquiring said value, and its offset and position within the tolerance zone (“% TOL) (proximity calculation) is indicated or output.

Conformity will be indicated already during the calibration procedure and for each measurement step and/or measured value of a quantity to be measured. The proximity calculation will also be performed for each single measured value immediately after the acceptance or acquisition of said measured value. As a result, the type of calculation of percentages (“% TOL) will be changed during the calibration, and the statement on said calibration will therefore become more accurate or more detailed/specific. An assessment may be performed on the basis of all conformity tests performed, for example if all conformity tests were successful.

For example, an absolute offset may be calculated by “measured value—calibration value”, and a relative offset by “(measured value—calibration value)/calibration value”.

Moreover, the location within the tolerance zone (“% TOL”) may be calculated by “amount of absolute offset/one-fold tolerance zone”, wherein the following stipulations may be made:
0% TOL: Calibration value equals measured value;
100% TOL: Tolerance limit exactly reached;
>100% TOL: beyond tolerance.

Here, the measurement uncertainty may affect the conformity evaluation. The smaller the measurement uncertainty is, the “safer”, that is, more meaningful the statement on the measured/calibration value will become with respect to the specification (e.g. the required tolerance limits or tolerance range or zone). Stated differently, the more “safely” will a value be found within or beyond the tolerance limits or the tolerance range or zone.

For example, the measured/calibration value may lie above/below an upper limit (for example a determined and/or defined control limit). The following cases may be labelled and distinguished, for example.
safely below the specification;
unsafely within the specification;
unsafely beyond the specification;
safely beyond the specification.

In the present context, the terms “safely” and “unsafely” indicate a probability. Usually, safely means for example 95% within or beyond the specification. Therefore, a percentage under 95% for example, does mean not “safely” or unsafely within or beyond the specification.

If conformity evaluations are included in the results report (calibration certificate), then
the statements will be confined to the covered measuring points and not to the instrument as such;
the evaluation will be performed online and will take under account the measurement uncertainties, and will be labelled as an uncertain evaluation in this latter case;
the source of evaluation (source of specification), i.e. the specification on which the calibration is based, will be indicated on the calibration certificate, so that a verification of the indicated/specified conditions, for example the tolerance limits, will be possible at any time;
the tolerance indications will be stated together with the results on the calibration certificate.

A plausibility test is the verification of a value as to whether it is or is not plausible in the first place, acceptable, consistent, reasonable, clear or comprehensible. Plausibility tests help to ensure the quality of calibration, for example. In some cases, the correctness of a value or result may not always be verifiable, but one has to recognize an existing (obvious) incorrectness of said value. If this test is error-free, an approval is possible.

Plausibility tests may comprise notifications that block an approval, that prevent an approval, alerts which are meant to attract attention to a result or a value, for example, and informative notifications which are only meant to inform about a result. Examples for a plausibility test may be: translation, reference to a specific site, work done, calibration object options, measurement uncertainties, calibration time, calibration state, test equipment, measured values, measurement series labelling (input values, output values), completeness of results, inconsistencies of a measurement series, approval, date, comments and many others. Therefore, the plausibility test will verify if the examined data are valid, inter alia.

In one, some or all calibration process(es), a drift report may be produced, if at least two calibration procedures exist or have been performed for one measurement instrument. The drift report serves to compare ascertained measured values from a calibration with previous calibrations over a (e.g. predetermined) time period. A drift report requires at least two calibration procedures. In the calibration process it is also possible to specify how large the allowed offset is, if values are to be compared between one calibration and a next one.

A drift report may comprise values from pre-existing calibrations, als well as a maximum drift (a largest value of all drifts in the ascertained history), a medium drift (a medium value from all drifts) which are ascertained from all pre-existing calibrations, and a note. The note may be a risk estimation, for example, and provide information on the level of probability that the test equipment will exhibit values beyond the tolerance zone in the next following calibration or in future. Therefore, it is also possible to predict the drift behavior of the test equipment.

Furthermore, the requirements of the process according to the invention may
comprise test equipment requirements which are provided by the test equipment, said test equipment requirements providing a suitability of the test equipment regarding the respective calibration value and/or a measurement uncertainty and/or a site for performing the calibration process; as well as
a choice of suitable pieces of test equipment for providing the indicated quantity to be measured;
a decision rule for conformity testing;
a risk evaluation process for measured values with respect to the corresponding measurement uncertainty.

A process for the risk evaluation of measurement steps with respect to the corresponding measurement uncertainty may minimize the risk during the calibration of an object under test according to the invention. Prerequisites for a possibly determined lower offset of a limit value are the individual estimation of the risk for a bad decision or faulty conformity tests (e.g. false-true-evaluations), as well as an approval.

Moreover, the calibration system of the process according to the invention may provide a method
for calculating measurement uncertainties.

The process according to the invention may further comprise:
ascertaining respective measurement uncertainties of the acquired measured values using the indicated process of calculating measurement uncertainties by use of the calibration system,
ascertaining the respective risks for the acquired measured values by use of the calibration systems,
   and
evaluating the respective ascertained measurement uncertainties and/or the respective ascertained risks according to selected compliance criteria.

One, some or all process(es) according to the invention may further comprise:
ascertaining respective measurement uncertainties for the acquired measured values by taking into account test equipment, measuring range and/or calibration processes, and/or calibration conditions and/or the site and/or local/ambient conditions and/or readability and/or multiple measurements and/or properties of the object under test.

Moreover, the calibration system of the process according to the invention may comprise a method of calculating corrected measured values that have been provided or acquired.

One, some or all process(es) according to the invention may further comprise:
ascertaining respective correction values for corrected measured values that have been provided or acquired, by taking into account test equipment, measuring range and/or calibration processes, and/or calibration conditions and/or the site and/or local/ambient conditions and/or readability and/or multiple measurements and/or properties of the object under test;
ascertaining the respective risks for the acquired measured values by use of the calibration systems,
evaluating the corrected measured values that have been provided or acquired and/or the respective ascertained risks according to selected compliance criteria.

In the process according to the invention, there may
exist at least one previous calibration of the assigned object under test, and
a drift report be produced when such a previous calibration is used, by a comparison with the current calibration of the assigned object under test.

In the process according to the invention, it is possible to perform a proximity calculation, risk ascertainment, risk evaluation and conformity test for each measured value after acquiring the same, before another measured value is acquired.

In the process according to the invention,
the calibration system may further indicate:
   at least one tool for performing said calibration process,
   at least one ambient condition for performing said calibration process,
   a site for performing said calibration process,
   at least one measurement uncertainty,
   at least one test equipment suitable for providing the indicated quantity to be measured,
   the completeness of translations,
   authorizations of the persons responsible for executing the approval,
   changes in the series of measurements if a results report exists that has not been approved yet,
   completeness of demands from the calibration master,
   evaluation according to selected compliance criteria,
      wherein
      the conformity test and/or the plausibility test and/or the conformity evaluation will be performed by taking into account at least one of the above indications.

A computer program product according to the invention will be further described, comprising instructions which will, during execution of said programs by a computer, cause said computer to execute the steps of one, some or all of the processes according to the invention for the calibration of an object under test.

Furthermore, a system for the calibration of an object under test will be described, comprising
test equipment, and
a calibration system,
wherein the calibration system serves to:
provide a plurality of calibration masters, a calibration master indicating the following items:
   an assigned object under test,
   a calibration process designated for the assigned object under test and including at least one calibration value,
   a quantity to be measured for the assigned object under test,
select a calibration master to which the object under test is assigned,
select requirements for the calibration of the object under test, said requirements comprising:
   a process for calculating the proximity of measured values of the quantity to be measured with respect to each calibration value and/or a measurement uncertainty;
   a specification assigned to the calibration value, the specification being determined with respect to the object under test;
define a test equipment suitable for the indicated quantity to be measured;
wherein the test equipment defined produces quantities to be measured for each calibration value, and
   wherein each of said quantities to be measured is transferred from said test equipment to said object under test, said object under test producing measured values in response to each of said transferred quantities to be measured,
acquire each of said produced measured values,
ascertain the proximity of each acquired measured value with respect to the determined specification, using said proximity calculation process in order to verify if each of said measured values is covered by said determined specification, wherein the proximity calculation is performed for each measured value after acquiring the same,
perform conformity tests for each acquired measured value,
ascertain, based on said conformity tests, if or if not the conformity evaluation of the calibration of the object under test has been successful,
perform a plausibility examination to check if or if not the calibration of said object under test may be approved definitely.

Furthermore, a system for the calibration of an object under test will be described, comprising
test equipment, and
a calibration system,
wherein the calibration system serves to:
provide a plurality of calibration masters, a calibration master indicating the following items:
   an assigned object under test,
   a calibration process designated for the assigned object under test and including at least one calibration value,
   a quantity to be measured for the assigned object under test,
select a calibration master to which the object under test is assigned,
select requirements for the calibration of the object under test, said requirements comprising:
   a process for calculating the proximity of measured values of the quantity to be measured with respect to each calibration value and/or a measurement uncertainty;
   a specification assigned to the calibration value, the specification being determined with respect to the object under test;
define a test equipment suitable for the indicated quantity to be measured;
wherein the object under test
   produces quantities to be measured for each calibration value, and
   each of said quantities to be measured is transferred from said object under test to said defined test equipment, wherein said test equipment produces measured values in response to each of said transferred quantities to be measured,
acquire each of said produced measured values,
ascertain the proximity of each acquired measured value with respect to the determined specification, using said proximity calculation process in order to verify if each of said measured values is covered by said determined specification, wherein the proximity calculation is performed for each measured value after acquiring the same,
perform conformity tests for each acquired measured value,
ascertain, based on said conformity tests, if or if not the conformity evaluation of the calibration of the object under test has been successful,
perform a plausibility examination to check if or if not the calibration of said object under test may be approved definitely.

A system according to the invention for the calibration of an object under test may further comprise a calibration system and a test equipment in which quantities to be measured are transferred from the test equipment to the object under test, wherein said object under test produces measured values in response to each transferred quantity to be measured, and/or may comprise a calibration system and a test equipment which quantities to be measured are transferred from said object under test to the defined test equipment, wherein said test equipment produces respective measured values in response to said transferred quantities to be measured.

Furthermore, the requirements of the systems according to the invention may
comprise test equipment requirements which are provided by the test equipment, said test equipment requirements providing a suitability of the test equipment regarding the respective calibration value and/or a measurement uncertainty and/or a site for performing the calibration process; as well as
a choice of suitable pieces of test equipment for providing the indicated quantity to be measured;
a decision rule for conformity testing;
a risk evaluation process for measured values with respect to the corresponding measurement uncertainty.

Moreover, the calibration system of the process according to the invention may provide a method for calculating measurement uncertainties, wherein, by means of said calibration system,
measurement uncertainties are respectively ascertained for the acquired measured values using the indicated process of calculating measurement uncertainties,
a risk is ascertained for the respective measured values,
   and
the respective ascertained measurement uncertainties and/or the respective ascertained risks are evaluated according to selected compliance criteria.

In the systems according to the invention, the calibration system may serve to
ascertain respective measurement uncertainties for the acquired measured values by taking into account test equipment, measuring range and/or calibration processes, and/or calibration conditions and/or the site and/or local/ambient conditions and/or readability and/or multiple measurements and/or properties of the object under test.

Moreover, the calibration system of the systems according to the invention may comprise a method of calculating corrected measured values that have been provided and/or acquired.

By the use of the calibration system, the systems according to the invention are able to
ascertain respective corrected measured values that have been provided and/or acquired by taking into account test equipment, measuring range and/or calibration process, and/or calibration conditions and/or the site and/or local/ambient conditions and/or readability and/or multiple measurements and/or properties of the object under test;
ascertain a risk for the respective measured values,
evaluate the corrected measured values that have been provided and/or acquired and/or the respective ascertained risk according to selected compliance criteria.

In the systems according to the invention, the calibration system may
be provided with at least one previous calibration of the assigned object under test, and
when such a previous calibration is used, a drift report may be produced by a comparison with the current calibration of the assigned object under test.

In the systems according to the invention, the calibration system may perform a proximity calculation, risk ascertainment, risk evaluation and conformity test for each measured value after acquiring the same, and before another measured value is acquired.

In the systems according to the invention,
the calibration system may further indicate:
   at least one tool for performing said calibration process,
   at least one ambient condition for performing said calibration process,
   a site for performing said calibration process,
   at least one measurement uncertainty,
   at least one test equipment suitable for providing the indicated quantity to be measured,
   the completeness of translations,
   authorizations of the persons responsible for executing the approval,
   changes in the series of measurements if a results report exists that has not been approved yet,
   completeness of demands from the calibration master,
   evaluation according to selected compliance criteria,
      wherein
      the conformity test and/or the plausibility test and/or the conformity evaluation will be performed by taking into account at least one of the above indications.

Furthermore, a test equipment according to the invention for use with an inventive calibration system for calibrating an object under test is described,

wherein the calibration system serves to:
provide a plurality of calibration masters, a calibration master indicating the following items:
   an assigned object under test,
   a calibration process designated for the assigned object under test and including at least one calibration value,
   a quantity to be measured for the assigned object under test,
select a calibration master to which the object under test is assigned,
select requirements for the calibration of the object under test, said requirements comprising:
   a process for calculating the proximity of measured values of the quantity to be measured with respect to each calibration value and/or a measurement uncertainty;
   a specification assigned to the calibration value, the specification being determined with respect to the object under test;
define a test equipment suitable for the indicated quantity to be measured;
wherein the test equipment defined
   produces quantities to be measured for each calibration value, and
   wherein each of said quantities to be measured is transferred from said test equipment to said object under test, said object under test producing measured values in response to each of said transferred quantities to be measured,
acquire each of said produced measured values,
ascertain the proximity of each acquired measured value with respect to the determined specification, using said proximity calculation process in order to verify if each of said measured values is covered by said determined specification, wherein the proximity calculation is performed for each measured value after acquiring the same,
perform conformity tests for each acquired measured value,
ascertain, based on said conformity tests, if or if not the conformity evaluation of the calibration of the object under test has been successful,
perform a plausibility examination to check if or if not the calibration of said object under test may be approved definitely.

A test equipment according to the invention for use with a calibration system according to the invention for calibrating an object under test is further described,

wherein the calibration system serves to:
provide a plurality of calibration masters, a calibration master indicating the following items:
   an assigned object under test,
   a calibration process designated for the assigned object under test and including at least one calibration value,
   a quantity to be measured for the assigned object under test,
select a calibration master to which the object under test is assigned,
select requirements for the calibration of the object under test, said requirements comprising:
   a process for calculating the proximity of measured values of the quantity to be measured with respect to each calibration value and/or a measurement uncertainty;
   a specification assigned to the calibration value, the specification being determined with respect to the object under test;
define a test equipment suitable for the indicated quantity to be measured;
wherein the object under test
   produces quantities to be measured for each calibration value, and
   each of said quantities to be measured is transferred from said object under test to said defined test equipment, wherein said test equipment produces measured values in response to each of said transferred quantities to be measured,
acquire each of said produced measured values,
ascertain the proximity of each acquired measured value with respect to the determined specification, using said proximity calculation process in order to verify if each of said measured values is covered by said determined specification, wherein the proximity calculation is performed for each measured value after acquiring the same,
perform conformity tests for each acquired measured value,
ascertain, based on said conformity tests, if or if not the conformity evaluation of the calibration of the object under test has been successful,
perform a plausibility examination to check if or if not the calibration of said object under test may be approved definitely.

Furthermore, the test equipment according to the invention for use with a calibration system according to the invention for the calibration of an object under test may comprise a calibration system and a test equipment, the quantities to be measured being transferred from said test equipment to said object under test, wherein said object under test, in response to the transferred quantities to be measured, produces measured values, and/or it may comprise a calibration system and a test equipment, the quantities to be measured being transferred from said object under test to said defined test equipment, wherein said test equipment produces respective measured values in response to the quantities to be measured transferred.

In the test equipment according to the invention for use with a calibration system according to the invention, the requirements of said calibration system may
comprise test equipment requirements which are provided by the test equipment, said test equipment requirements providing a suitability of the test equipment regarding the respective calibration value and/or a measurement uncertainty and/or a site for performing the calibration process; as well as
a choice of suitable pieces of test equipment for providing the indicated quantity to be measured;
a decision rule for conformity testing;
a risk evaluation process for measured values with respect to the corresponding measurement uncertainty.

In the test equipment according to the invention for use with a calibration system according to the invention, said calibration system may provide a method for calculating measurement uncertainties,

wherein, by means of said calibration system,
measurement uncertainties are respectively ascertained for the acquired measured values using the indicated process of calculating measurement uncertainties,
a risk is ascertained for the respective measured values,
   and
the respective ascertained measurement uncertainties and/or the respective ascertained risks are evaluated according to selected compliance criteria.

In the testing means according to the invention for use with an inventive calibration system, the use of said calibration system allows to
ascertain respective measurement uncertainties for the acquired measured values by taking into account test equipment, measuring range and/or calibration processes, and/or calibration conditions and/or the site and/or local/ambient conditions and/or readability and/or multiple measurements and/or properties of the object under test.

Moreover, in the test equipment according to the invention for use with a calibration system according to the invention, said calibration system may comprise a calculation method for corrected measured values that have been provided and/or acquired.

Furthermore, said calibration system serves to
ascertain respective corrected values for corrected measured values that have been provided and/or acquired, by taking into account test equipment, measuring range and/or calibration process, and/or calibration conditions and/or site and/or local/ambient conditions and/or readability and/or multiple measurements and/or properties of the object under test;
ascertain a risk for the respective measured values,
evaluate the corrected measured values that have been provided and/or acquired and/or the respective ascertained risk according to selected compliance criteria.

In the test equipment according to the invention for use with a calibration system according to the invention, said calibration system may
be provided with at least one previous calibration of the assigned object under test, and
when such a previous calibration is used, a drift report may be produced by a comparison with the current calibration of the assigned object under test.

In the test equipment according to the invention for use with a calibration system according to the invention, said calibration system may perform a proximity calculation, risk ascertainment, risk evaluation and conformity test for each measured value after acquiring the same, and before another measured value is acquired.

In the test equipment according to the invention for use with a calibration system according to the invention,
the calibration system may further indicate:
   at least one tool for performing said calibration process,
   at least one ambient condition for performing said calibration process,
   a site for performing said calibration process,
   at least one measurement uncertainty,
   at least one test equipment suitable for providing the indicated quantity to be measured,
   the completeness of translations,
   authorizations of the persons responsible for executing the approval,
   changes in the series of measurements if a results report exists that has not been approved yet,
   completeness of demands from the calibration master,
   evaluation according to selected compliance criteria,
      wherein
      the conformity test and/or the plausibility test and/or the conformity evaluation will be performed by taking into account at least one of the above indications.

Furthermore, a calibration system according to the invention for use with a test equipment according to the invention for calibrating an object under test is described,

wherein the calibration system serves to:
provide a plurality of calibration masters, a calibration master indicating the following items:
   an assigned object under test,
   a calibration process designated for the assigned object under test and including at least one calibration value,
   a quantity to be measured for the assigned object under test,
select a calibration master to which the object under test is assigned,
select requirements for the calibration of the object under test, said requirements comprising:
   a process for calculating the proximity of measured values of the quantity to be measured with respect to each calibration value and/or a measurement uncertainty;
   a specification assigned to the calibration value, the specification being determined with respect to the object under test;
define a test equipment suitable for the indicated quantity to be measured; wherein the test equipment defined
   produces quantities to be measured for each calibration value, and
   wherein each of said quantities to be measured is transferred from said test equipment to said object under test, said object under test producing measured values in response to each of said transferred quantities to be measured,
acquire each of said produced measured values,
ascertain the proximity of each acquired measured value with respect to the determined specification, using said proximity calculation process in order to verify if each of said measured values is covered by said determined specification, wherein the proximity calculation is performed for each measured value after acquiring the same,
perform conformity tests for each acquired measured value,
ascertain, based on said conformity tests, if or if not the conformity evaluation of the calibration of the object under test has been successful,
perform a plausibility examination to check if or if not the calibration of said object under test may be approved definitely.

Furthermore, a calibration system according to the invention for use with a test equipment according to the invention for calibrating an object under test is described, wherein the calibration system serves to:
provide a plurality of calibration masters, a calibration master indicating the following items:
   an assigned object under test,
   a calibration process designated for the assigned object under test and including at least one calibration value,
   a quantity to be measured for the assigned object under test,
select a calibration master to which the object under test is assigned,
select requirements for the calibration of the object under test, said requirements comprising:
   a process for calculating the proximity of measured values of the quantity to be measured with respect to each calibration value and/or a measurement uncertainty;
   a specification assigned to the calibration value, the specification being determined with respect to the object under test;
define a test equipment suitable for the indicated quantity to be measured;
wherein the object under test
   produces quantities to be measured for each calibration value, and
   each of said quantities to be measured is transferred from said object under test to said defined test equipment, wherein said test equipment produces measured values in response to each of said transferred quantities to be measured,
acquire each of said produced measured values,
ascertain the proximity of each acquired measured value with respect to the determined specification, using said proximity calculation process in order to verify if each of said measured values is covered by said determined specification, wherein the proximity calculation is performed for each measured value after acquiring the same,
perform conformity tests for each acquired measured value,
ascertain, based on said conformity tests, if or if not the conformity evaluation of the calibration of the object under test has been successful,
perform a plausibility examination to check if or if not the calibration of said object under test may be approved definitely.

For calibrating an object under test, the calibration system according to the invention for use with a test equipment according to the invention may further comprise a calibration system and a test equipment, the quantities to be measured being transferred from said test equipment to said object under test, wherein said object under test, in response to the transferred quantities to be measured, produces measured values, and/or it may comprise a calibration system and a test equipment, the quantities to be measured being transferred from said object under test to said defined test equipment, wherein said test equipment produces respective measured values in response to the quantities to be measured transferred.

In the calibration system according to the invention for use with a test equipment according to the invention, the requirements of said calibration system may
comprise test equipment requirements which are provided by the test equipment, said test equipment requirements providing a suitability of the test equipment regarding the respective calibration value and/or a measurement uncertainty and/or a site for performing the calibration process; as well as
a choice of suitable pieces of test equipment for providing the indicated quantity to be measured;
a decision rule for conformity testing;
a risk evaluation process for measured values with respect to the corresponding measurement uncertainty.

In the calibration system according to the invention for use with a test equipment according to the invention, said calibration system may provide a method for calculating measurement uncertainties, wherein said calibration system serves to
acquire measurement uncertainties for each of the acquired measured values using the indicated process of calculating measurement uncertainties,
ascertain a risk for the respective measured values,
   and
evaluate the respective ascertained measurement uncertainties and/or the respective ascertained risks according to selected compliance criteria.

In the calibration system according to the invention for use with a test equipment according to the invention, said calibration system may serve to
ascertain respective measurement uncertainties for the acquired measured values by taking into account test equipment, measuring range and/or calibration processes, and/or calibration conditions and/or the site and/or local/ambient conditions and/or readability and/or multiple measurements and/or properties of the object under test.

Moreover, in the calibration system according to the invention for use with a test equipment according to the invention, said calibration system may comprise a calculation method for corrected measured values that have been provided and/or acquired.

Furthermore, said calibration system serves to
ascertain respective corrected values for corrected measured values that have been provided and/or acquired, by taking into account test equipment, measuring range and/or calibration process, and/or calibration conditions and/or site and/or local/ambient conditions and/or readability and/or multiple measurements and/or properties of the object under test;
ascertain a risk for the respective measured values,
evaluate the corrected measured values that have been provided and/or acquired and/or the respective ascertained risk according to selected compliance criteria.

In the calibration system according to the invention for use with a test equipment according to the invention, said calibration system may
be provided with at least one previous calibration of the assigned object under test, and
when such a previous calibration is used, a drift report may be produced by a comparison with the current calibration of the assigned object under test.

In the calibration system according to the invention for use with a test equipment according to the invention, said calibration system may, for each measured value, perform a proximity calculation, a risk ascertainment, risk evaluation and conformity test after acquiring the same, before another measured value is acquired.

In the calibration system according to the invention for use with a test equipment according to the invention,
the calibration system may further indicate:
   at least one tool for performing said calibration process,
   at least one ambient condition for performing said calibration process,
   a site for performing said calibration process,
   at least one measurement uncertainty,
   at least one test equipment suitable for providing the indicated quantity to be measured,
   the completeness of translations,
   authorizations of the persons responsible for executing the approval,
   changes in the series of measurements if a results report exists that has not been approved yet,
   completeness of demands from the calibration master,
   evaluation according to selected compliance criteria,
      wherein
      the conformity test and/or the plausibility test and/or the conformity evaluation will be performed by taking into account at least one of the above indications.

It should be noted that the object under test, the test equipment and the calibration system do not necessarily have to be located at the same site. To the contrary, the object under test, the test equipment and the calibration system may (each) be located at a different site, i.e. a calibration according to the invention may be performed irrespective of their respective distances from one another.

### SHORT DESCRIPTION OF THE DRAWINGS

Exemplary embodiments of the invention will now be described with respect to the accompanying drawings.

FIG. 1 shows an example for an environment where an object under test which needs to be calibrated is calibrated using a process according to the invention;

FIG. 2 shows a flow chart of the process according to the invention in a direction A for the calibration of an object under test from FIG. 1;

FIG. 3 shows an example for an environment where an object under test which needs to be calibrated is calibrated using a process according to the invention;

FIG. 4 shows a flow chart of the process according to the invention in a direction B for the calibration of an object under test from FIG. 3.

### DESCRIPTION OF PREFERRED EMBODIMENTS

Below, the invention will be further explained using embodiments shown in the drawings, where elements with substantially similar functions are provided with the same reference signs throughout the drawings.

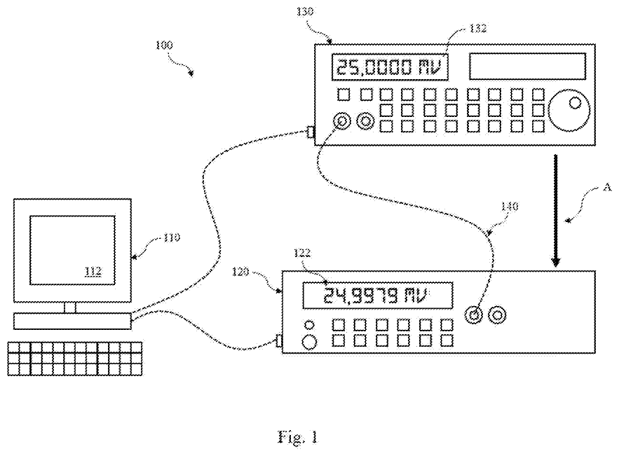

FIG. 1 shows an example of a measurement or laboratory environment 100 where an object under test that needs to be calibrated may be calibrated using a process according to the invention.

In FIG. 1, the calibration process is illustrated by electronic instruments, such as voltage instrument (voltmeter), cable and voltage measuring instrument, merely as an example.

FIG. 1 illustrates, by way of example, the calibration of DC-voltmeters.

However, the present invention is not limited to this, as a variety of different objects under test, measuring instruments, artifacts, test equipment and tools that need calibration may be used in the calibration process, as already mentioned above.

The exemplary measuring and laboratory environment 100 includes a calibration system 110, an object under test 120 that needs to be calibrated and test equipment 130, as well as a tool 140.

The test equipment 130 is connected via a tool 140 which is represented as a cable. Depending on the objects under test 120 that need to be calibrated, it is possible to omit any tool 140 or to use a plurality of them. The use of an appropriate tool 140 depends in particular on the type and the properties of the object under test that needs to be calibrated. The calibration system or evaluation system 110 is represented in FIG. 1 by a computer which provides a plurality of calibration masters 112 and which is connected to the object under test 120 that needs to be calibrated and to the test equipment 130. These connections will also depend on the type and the properties of the object under test that needs to be calibrated or the test equipment used, i.e. these connections may also be optional, that is, may not be necessary, for example.

Here, the voltmeter of FIG. 1 may be inspected or calibrated for a plurality of ranges, for example 100 mV, 0 V. 1 V, 10 V, 100 V, 750 V. 1000 V or other (e.g. also negative) values or value ranges.

In the process according to the invention for calibrating an object under test 120 according to FIG. 1, quantities to be measured are produced for each calibration value 132 by use of the defined test equipment 130. The quantity to be measured or the calibration value 132, for example 25.0000 mV, is subsequently transferred to the object under test 120. In FIG. 1, this is illustrated by direction A. In response to the transferred quantity to be measured, the object under test 120 acquires and produces a measured value 122, e.g. 24.9979 mV. Following the transferal and acquisition, the next quantity to be measured may be produced and transferred, or, optionally, corrections can be made.

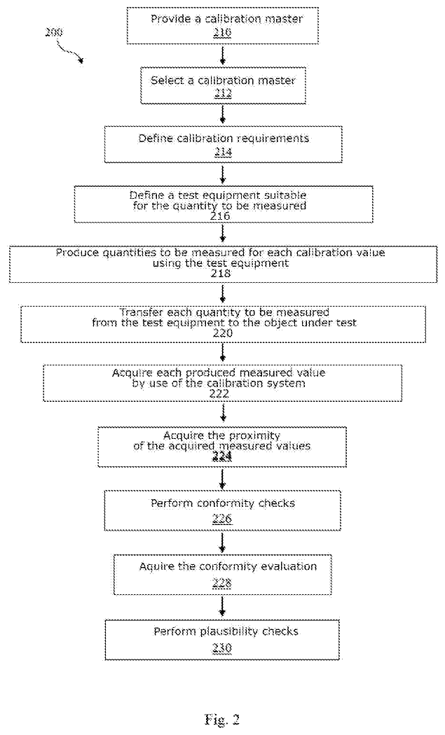

The process for calibrating an object under test illustrated by direction A in FIG. 1 will now be described with reference to FIG. 2.

First, according to step 210 of FIG. 2, a calibration master 112 is provided by the calibration system 110, indicating an assigned object under test 120, a calibration process including a calibration value 132, for example 25.0000 mV, and a quantity to be measured (figure and unit), inter glia.

According to step 212, a calibration master 112 suitable for the calibration is selected or newly created, if necessary. In addition to this, additional requirements for the calibration of the object under test 120 are defined in step 214. They comprise a process for the proximity calculation of measured values of the quantities to be measured with respect to the corresponding calibration values 132 and/or a measurement uncertainty, as well as a specification assigned to the calibration value 132, said specification being determined with respect to the object under test and may also be determined by a zero value or may include the latter, for example.

Step 216 defines a test equipment 130 suitable for the indicated quantity to be measured, and at the same time, a (new) test equipment 130 may be created, which has not (yet) been included in the requirements or the choice of test equipment. Additionally or alternatively, it is also possible to select or determine a test equipment already included in said choice or requirements. In particular, the calibration master 112 may provide a suggestion for an appropriate test equipment 130 or, in case an appropriate test equipment has not been produced or does not exist, a (new) test equipment may be created.

Step 218 produces a quantity to be measured or a calibration value 132, for example 25.0000 mV, by the use of said test equipment 130, which is subsequently transferred from said test equipment to said object under test 120 (i.e. in a direction A) in step 220.

In response to the transferred quantity to be measured, the object under test 120 acquires and produces a measured value 122, e.g. 24.9979 mV. Each of said measured value 122 and said calibration value 132 is acquired in step 222 by means of a calibration system 110 and is recorded and stored in the calibration master 112.

For each acquired measured value, a position with respect to a determined specification or tolerance is ascertained in step 224, by use of a proximity calculation process using the calibration system 110. However, it is also possible that the specification comprises a zero value, that is, no tolerance may be required for the calibration.

A tolerance that can be chosen is for example ±0.00475 mV, which allows for a minimum of 24.99525 mV and a maximum of 25.00475 mV.

During the proximity calculation, it is checked if the respective measured value 122 can be found within the determined specification, said proximity calculation being performed for each measured value 122 after acquiring the same.

In step 226, conformity tests are performed for each acquired measured value 122, and it is checked by means of the calibration system 110 and on the basis of said conformity tests if or if not the conformity evaluation of the calibration of the object under test 120 has been successful.

Subsequently, plausibility checks are performed in step 230 by means of the calibration system 110 in order to verify if or if not the calibration of said object under test 120 may be definitely approved.

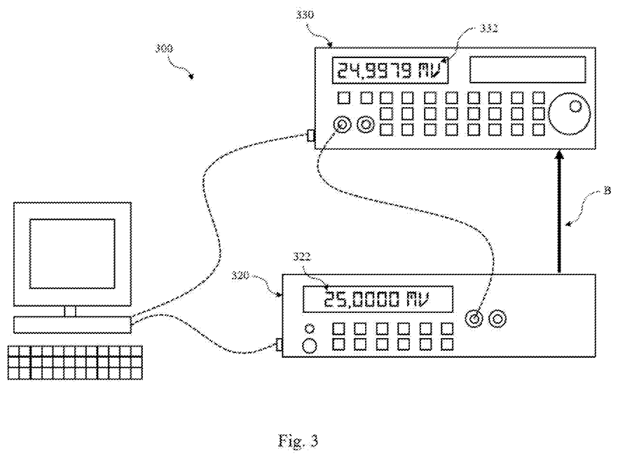

FIG. 3 illustrates the calibration process also by electronic instruments such as voltage instrument (voltmeter), cable and voltage measuring instrument, only by way of example.

FIG. 3 illustrates, by way of example, the calibration of DC-voltmeters.

The measurement, laboratory or calibration environment of FIG. 3 is substantially the same as the measurement, laboratory or calibration environment of FIG. 1.

Als a difference to FIG. 1, FIG. 3 describes a process according to the invention for the calibration of an object under test 320, wherein quantities to be measured are produced for each calibration value 322 by use of the object under test 320. The quantity to be measured or the calibration value 322, for example 25,0000 mV, is subsequently transferred from the object under test 320 to the defined test equipment 330. In FIG. 3, this is illustrated by direction B. In response to the transferred quantity to be measured, the defined test equipment 330 acquires and produces a measured value 332, e.g. 24.9979 mV. Following the transferal and acquisition, the next quantity to be measured may be produced and transferred, or, optionally, corrections can be made.

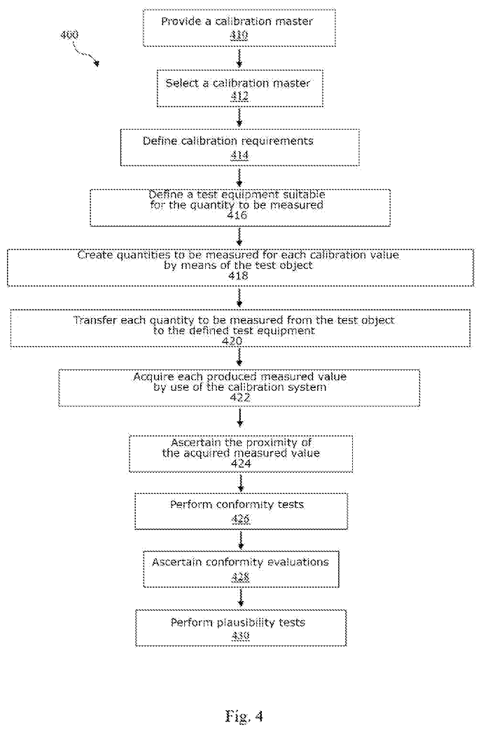

The process for calibrating an object under test illustrated by direction B in FIG. 3 will now be described with reference to FIG. 4.

First, according to step 410 of FIG. 2, a calibration master 112 is provided by the calibration system 110, indicating an assigned object under test 320, a calibration process including a calibration value 322, for example 25.0000 mV, and a quantity to be measured (figure and unit), inter alia.

According to step 412, a calibration master 112 suitable for the calibration is selected or newly created, if necessary. In addition to this, additional requirements for the calibration of the object under test 120 are defined in step 414. They comprise a process for the proximity calculation of measured values of the quantities to be measured with respect to the corresponding calibration values 322 and/or a measurement uncertainty, as well as a specification assigned to the calibration value 322, said specification being determined with respect to the object under test and may also be determined by a zero value.

Step 416 defines a test equipment 330 suitable for the indicated quantity to be measured, and at the same time, a (new) test equipment 330 may be created, which has not (yet) been included in the requirements or the choice of test equipment. Additionally or alternatively, it is also possible to select or determine a test equipment already included in said choice or requirements. In particular, the calibration master 112 may provide a suggestion for an appropriate test equipment 330 or, in case an appropriate test equipment has not been produced or does not exist, a (new) test equipment may be created.

Step 418 produces a measured quantity or a calibration value 322, for example 25.0000 mV, by the use of said object under test 320, which is subsequently, in step 420, transferred from said object under test 320 to said test equipment 330 (i.e. in a direction B).

In response to the transferred quantity to be measured, the defined test equipment 330 acquires and produces a measured value 332, e.g. 24.9979 mV.

Each of said measured value 332 and said calibration value 322 is acquired in step 422 by means of a calibration system 110 and is recorded and stored in the calibration master 112.

For each acquired measured value, a position with respect to a determined specification or tolerance is ascertained in step 424, by use of a proximity calculation process using the calibration system 110. However, it is also possible that the specification comprises a zero value, that is, no tolerance may be required for the calibration.

A tolerance that can be chosen is for example ±0.00475 mV, which allows for a minimum of 24.99525 mV and a maximum of 25.00475 mV.

During the proximity calculation, it is checked if the respective measured value 332 can be found within the determined specification, said proximity calculation being performed for each measured value 332 after acquiring the same.

In step 226, conformity tests are performed for each acquired measured value 332, and it is checked by means of the calibration system 110 and on the basis of said conformity tests if or if not the conformity evaluation of the calibration of the object under test 320 has been successful.

Subsequently, plausibility checks are performed in step 230 by means of the calibration system 110 in order to verify if or if not the calibration of said object under test 320 may be definitely approved.

It has to be noted that the process described in FIGS. 1 and 2 and the process described in FIGS. 3 and 4 may be performed for calibrating an object under test. Stated otherwise, the process described in FIGS. 1 and 2 and the process described in FIGS. 3 and 4 may be performed individually and/or alternatingly or together/at the same time.

In the processes described, a plurality of measured values or series of measured values may be verified and verified again, any time, for example with respect to conformity, proximity and plausibility. This may be advantageous if, for example, a measured value as acquired is obviously faulty. In such a case, the calibration may be stopped/halted, the measurement environment may be searched for source of errors and then the calibration may be continued. Therefore, a bad value will not contribute to the calibration. In this way, the calibration process according to the invention avoids calibration errors. This increases the calibration accuracy and reduces or avoids lengthy calibration or waiting times, and therefore achieves time savings. Stated otherwise, the calibration does not necessarily have to be (fully) completed in order to identify and minimize possible sources of errors.

In comparison with conventional approaches, the processes described herein do furthermore take into account a variety of dependencies. For example dependencies between requirements, methods, quantities to be measured, test equipment, sites, ambient conditions, measurement uncertainties, correction values or the like, and/or other dependencies as described herein.

We claim:

1. A process for the calibration of an object under test, comprising the following steps:
providing a plurality of calibration masters by means of a calibration system, a calibration master indicating the following items:
an assigned object under test,
a calibration process designated for the assigned object under test and including at least one calibration value,
a quantity to be measured for the assigned object under test,
selecting a calibration master to which the object under test is assigned,
defining requirements for the calibration of the object under test, said requirements comprising:
a process for calculating the proximity of measured values of the quantity to be measured with respect to each calibration value and/or a measurement uncertainty;
a specification assigned to the calibration value, the specification being determined with respect to the object under test;
defining a test equipment appropriate for the indicated quantity to be measured;
said process further comprising the following steps:
producing quantities to be measured for each calibration value by use of the defined test equipment, and
transferring each of said quantities to be measured from said test equipment to said object under test, wherein said object under test produces measured values in response to each of said transferred quantities to be measured,
acquiring each of said produced measured values by means of said calibration system,
ascertaining the proximity of each acquired measured value with respect to the determined specification by means of said calibration system using said proximity calculation process in order to verify if each of said measured values is covered by said determined specification, wherein for each measured value, the proximity calculation is performed after acquiring the same,
performing conformity tests on each acquired measured value,
determining by means of said calibration system and based on the conformity tests performed, if or if not the conformity evaluation of the test specimen calibration has been successful
performing, by means of said calibration system, a plausibility check to verify if or if not the calibration of said object under test may be definitely approved.

2. A process for the calibration of an object under test, comprising the following steps:
providing a plurality of calibration masters by the use of a calibration system, wherein a calibration master indicates the following items:
an assigned object under test,
a calibration process designated for the assigned object under test and including at least one calibration value,
a quantity to be measured for the assigned object under test,
selecting a calibration master to which the object under test is assigned,
defining requirements for the calibration of the test equipment, said requirements comprising:
a process for calculating the proximity of measured values of said quantity to be measured with respect to each calibration value and/or a measurement uncertainty;
a specification assigned to the calibration value, the specification being determined with respect to the object under test;
defining a test equipment appropriate for the indicated quantity to be measured;
said process further comprising the following steps:
producing quantities to be measured for each calibration value by use of the object under test, and
transferring each of said quantities to be measured from said object under test to said defined test equipment, wherein said test equipment produces measured values in response to each of said transferred quantities to be measured,
acquiring each of said produced measured values by means of said calibration system,
ascertaining the proximity of each acquired measured value with respect to the determined specification by means of said calibration system using said proximity calculation process in order to verify if each of said measured values is covered by said determined specification, wherein for each measured value, the proximity calculation is performed after acquiring the same,
performing conformity tests on each acquired measured value,
determining, by means of said calibration system and based on the conformity tests performed, if or if not the conformity evaluation of the test specimen calibration has been successful,
performing, by means of said calibration system, a plausibility check to verify if or if not the calibration of said object under test may be definitely approved.

3. A process including the steps according to claim 1 and claim 2.

4. The process according to one of the preceding claims, wherein said requirements further comprise
test equipment requirements which are provided by the test equipment, said test equipment requirements providing a suitability of the test equipment regarding the respective calibration value and/or a measurement uncertainty and/or a site for performing the calibration process; as well as
a choice of suitable test equipment for providing the indicated quantity to be measured;
a decision rule for conformity testing;
a risk evaluation process for measured values regarding the respective measurement uncertainty.

5. The process according to one of the preceding claims, wherein said calibration system comprises a method for calculating measurement uncertainties, said process further comprising:
ascertaining respective measurement uncertainties of the acquired measured values using the indicated process of calculating measurement uncertainties by use of the calibration system,
ascertaining the respective risks for the acquired measured values by use of the calibration systems,
and
evaluating the respective ascertained measurement uncertainties and/or the respective ascertained risks according to selected compliance criteria.

6. The process according to one of the preceding claims, wherein
at least one previous calibration of the assigned object under test exists, and
when using such a previous calibration, a drift report is produced by a comparison with the current calibration of the assigned object under test.

7. The process according to one of the preceding claims, wherein a proximity calculation, risk ascertainment, risk evaluation and conformity test are performed for each measured value after acquiring the same and before another measured value is acquired.

8. The process according to one of the preceding claims, wherein
the calibration system further indicates:
at least one tool for performing said calibration process,
at least one ambient condition for performing said calibration process,
a site for performing said calibration process,
at least one measurement uncertainty,
at least one test equipment suitable for providing the indicated quantity to be measured,
the completeness of translations,
authorizations of the persons responsible for executing the approval,
changes in the series of measurements if a results report exists that has not been approved yet,
completeness of demands from the calibration master,
evaluation according to selected compliance criteria,
wherein
the conformity test and/or the plausibility test and/or the conformity evaluation will be performed by taking into account at least one of the above indications.

9. Computer program product comprising instructions which cause a computer to execute the process according to claim 1, 2 and/or 3 when said program is executed by said computer.

10. A system for calibrating an object under test, comprising:
a test equipment, and
a calibration system,
wherein said calibration system serves to:
provide a plurality of calibration masters, a calibration master indicating the following items:
an assigned object under test,
a calibration process designated for the assigned object under test and including at least one calibration value,
a quantity to be measured for the assigned object under test,
select a calibration master to which the object under test is assigned,
select requirements for the calibration of the object under test, said requirements comprising:
a process for calculating the proximity of measured values of the quantity to be measured with respect to each calibration value and/or a measurement uncertainty;
a specification assigned to the calibration value, the specification being determined with respect to the object under test;
define a test equipment suitable for the indicated quantity to be measured;
wherein the test equipment defined
produces quantities to be measured for each calibration value, and
wherein each of said quantities to be measured is transferred from said test equipment to said object under test, said object under test producing measured values in response to each of said transferred quantities to be measured,
acquire each of said produced measured values,
ascertain the proximity of each acquired measured value with respect to the determined specification, using said proximity calculation process in order to verify if each of said measured values is covered by said determined specification, wherein the proximity calculation is performed for each measured value after acquiring the same,
perform conformity tests for each acquired measured value,
ascertain, based on said conformity tests, if or if not the conformity evaluation of the calibration of the object under test has been successful,
perform a plausibility examination to check if or if not the calibration of said object under test may be approved definitely.

11. A system for calibrating an object under test, comprising:
a test equipment, and
a calibration system,
wherein said calibration system serves to:
provide a plurality of calibration masters, the calibration master indicating the following items:
an assigned object under test,
a calibration process designated for the assigned object under test and including at least one calibration value,
a quantity to be measured for the assigned object under test,
select a calibration master to which the object under test is assigned,
select requirements for the calibration of the object under test, said requirements comprising:
a process for calculating the proximity of measured values of the quantity to be measured with respect to each calibration value and/or a measurement uncertainty;
a specification assigned to the calibration value, the specification being determined with respect to the object under test;
define a test equipment suitable for the indicated quantity to be measured;
wherein the object under test
produces quantities to be measured for each calibration value, and
each of said measurement categories is transmitted from said equipment under test to said defined testing means, wherein said testing means produces measured values in response to each of said transmitted measurement categories,
acquire each of said produced measured values,
ascertain the proximity of each acquired measured value with respect to the determined specification, using said proximity calculation process in order to verify if each of said measured values is covered by said determined specification, wherein the proximity calculation is performed for each measured value after acquiring the same,
perform conformity tests for each acquired measured value,
ascertain, based on said conformity tests, if or if not the conformity evaluation of the calibration of the object under test has been successful,
perform a plausibility examination to check if or if not the calibration of said object under test may be approved definitely.

12. The system according to claim 10 and claim 11.
